(19) United States
(12) Patent Application Publication
(10) Pub. No.: US 2025/0062729 A1
(43) Pub. Date: Feb. 20, 2025

(54) EFFICIENCY IMPROVEMENT IN A WIRELESS TRANSMISSION CIRCUIT

(71) Applicant: Qorvo US, Inc., Greensboro, NC (US)

(72) Inventor: Nadim Khlat, Cugnaux (FR)

(21) Appl. No.: 18/763,182

(22) Filed: Jul. 3, 2024

Related U.S. Application Data
(60) Provisional application No. 63/533,375, filed on Aug. 18, 2023.

(51) Int. Cl. H03F 3/24; H04B 1/40

(52) U.S. Cl. CPC H03F 3/245; H04B 1/40; H03F 2200/451

(57) ABSTRACT

Efficiency improvement in a wireless transmission circuit is disclosed herein. The wireless transmission circuit includes a power amplifier circuit that amplifies a radio frequency (RF) signal based on an average power tracking (APT) voltage. In an embodiment, the power amplifier circuit includes a carrier amplifier and a peak amplifier. The carrier amplifier is always active to amplify the RF signal to an average output power, and the peak amplifier is only active when needed to further amplify the RF signal beyond the average output power. Herein, an activation point of the peak amplifier is dynamically adjusted in accordance with the average output power of the RF signal. As a result, it is possible to eliminate excessive headroom in the APT voltage to thereby improve efficiency of the power amplifier circuit and the wireless transmission circuit as a whole.

### RELATED APPLICATIONS

This application claims the benefit of U.S. provisional patent application Ser. No. 63/533,375, filed on Aug. 18, 2023, the disclosure of which is hereby incorporated herein by reference in its entirety.

### FIELD OF THE DISCLOSURE

The technology of the disclosure relates generally to a wireless transmission circuit and in particular to a wireless transmission circuit employing a load-line modulation power amplifier circuit.

### BACKGROUND

The fifth generation (5G) system has been widely regarded as the next generation wireless communication system beyond the current third generation (3G) and fourth generation (4G) systems. In this regard, a 5G-capable wireless communication device is expected to achieve higher data rates, improved coverage range, enhanced signaling efficiency, and reduced latency.

The 5G-capable wireless communication device typically includes multiple transmitters to simultaneously transmit multiple 5G radio frequency (RF) signals under such schemes as Carrier Aggregation (CA) and Evolved-Universal Terrestrial Radio Access (E-UTRA) New Radio (NR) Dual Connectivity (DC) (ENDC). Since the transmitters typically transmit the 5G RF signals in a millimeter wave spectrum, the RF signals can be more susceptible to propagation attenuation and interference. To help mitigate propagation attenuation and maintain desirable data throughput, the 5G-capable wireless communication device typically employs multiple power amplifiers to amplify the RF signals to desired power levels before transmitting the RF signals from the transmitters. As such, it is desirable to ensure that the power amplifiers can operate with optimal efficiency, especially when the RF signals are transmitted with different peak-to-average ratios (PARs).

### SUMMARY

Embodiments of the disclosure relate to efficiency improvement in a wireless transmission circuit. The wireless transmission circuit includes a power amplifier circuit that amplifies a radio frequency (RF) signal based on an average power tracking (APT) voltage. In an embodiment, the power amplifier circuit includes a carrier amplifier and a peak amplifier. The carrier amplifier is always active to amplify the RF signal to an average output power, and the peak amplifier is only active when needed to further amplify the RF signal beyond the average output power. Herein, an activation point of the peak amplifier is dynamically adjusted in accordance with the average output power of the RF signal. As a result, it is possible to eliminate excessive headroom in the APT voltage to thereby improve efficiency of the power amplifier circuit and the wireless transmission circuit as a whole.

In one aspect, a wireless transmission circuit is provided. The wireless transmission circuit includes a power amplifier circuit. The power amplifier circuit includes a carrier amplifier. The carrier amplifier is always activated to amplify an RF signal based on an APT voltage. The power amplifier circuit also includes a peak amplifier. The peak amplifier is activated by a bias voltage to further amplify the RF signal based on the APT voltage. The power amplifier circuit also includes a bias circuit. The bias circuit is configured to generate the bias voltage to thereby activate the peak amplifier when an output power of the RF signal is higher than or equal to a threshold value. The bias circuit is also configured to refrain from generating the bias voltage to thereby deactivate the peak amplifier when the output power of the RF signal is lower than the threshold value. The wireless transmission circuit also includes a power management integrated circuit (PMIC). The PMIC is configured to generate the APT voltage based on a target voltage. The wireless transmission circuit also includes a transceiver circuit. The transceiver circuit is configured to generate and provide the RF signal to the power amplifier circuit. The transceiver circuit is also configured to indicate the output power of the RF signal to the bias circuit. The transceiver circuit is also configured to generate the target voltage based on the output power of the RF signal.

In another aspect, a wireless device is provided. The wireless device includes a wireless transmission circuit. The wireless transmission circuit includes a power amplifier circuit. The power amplifier circuit includes a carrier amplifier. The carrier amplifier is always activated to amplify an RF signal based on an APT voltage. The power amplifier circuit also includes a peak amplifier. The peak amplifier is activated by a bias voltage to further amplify the RF signal based on the APT voltage. The power amplifier circuit also includes a bias circuit. The bias circuit is configured to generate the bias voltage to thereby activate the peak amplifier when an output power of the RF signal is higher than or equal to a threshold value. The bias circuit is also configured to refrain from generating the bias voltage to thereby deactivate the peak amplifier when the output power of the RF signal is lower than the threshold value. The wireless transmission circuit also includes a PMIC. The PMIC is configured to generate the APT voltage based on a target voltage. The wireless transmission circuit also includes a transceiver circuit. The transceiver circuit is configured to generate and provide the RF signal to the power amplifier circuit. The transceiver circuit is also configured to indicate the output power of the RF signal to the bias circuit. The transceiver circuit is also configured to generate the target voltage based on the output power of the RF signal.

In another aspect, a method for improving wireless transmission efficiency is provided. The method includes always activating a carrier amplifier to amplify an RF signal based on an APT voltage. The method also includes activating a peak amplifier by a bias voltage to further amplify the RF signal based on the APT voltage. The method also includes generating the bias voltage to thereby activate the peak amplifier when an output power of the RF signal is higher than or equal to a threshold value. The method also includes refraining from generating the bias voltage to thereby deactivate the peak amplifier when the output power of the RF signal is lower than the threshold value.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure and, together with the description, serve to explain the principles of the disclosure.

FIG. 1 is a schematic diagram of an exemplary wireless transmission circuit wherein embodiments of the present disclosure can be employed to improve efficiency of a power amplifier circuit;

FIG. 2 is a schematic diagram providing an exemplary illustration of the power amplifier circuit in FIG. 1;

FIG. 3 is a schematic diagram illustrating an exemplary equivalent electrical model of the power amplifier circuit in FIG. 2;

FIG. 4 is a graphic diagram providing an exemplary illustration of an efficiency improvement scheme according to one embodiment of the present disclosure;

FIG. 5 is a schematic diagram providing an exemplary illustration of a voltage transition interval between consecutive symbols and consecutive timeslots;

FIG. 6 is a schematic diagram illustrating a configuration of the voltage transition interval in FIG. 5;

FIG. 7 is a graphic diagram providing an exemplary illustration of another efficiency improvement scheme according to another embodiment of the present disclosure;

FIG. 8 is a schematic diagram of an exemplary communication device wherein the wireless transmission circuit of FIG. 1 can be provided; and

FIG. 9 is a flowchart of an exemplary process for improving efficiency of the wireless transmission circuit of FIG. 1.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments of the disclosure relate to efficiency improvement in a wireless transmission circuit. The wireless transmission circuit includes a power amplifier circuit that amplifies a radio frequency (RF) signal based on an average power tracking (APT) voltage. In an embodiment, the power amplifier circuit includes a carrier amplifier and a peak amplifier. The carrier amplifier is always active to amplify the RF signal to an average output power, and the peak amplifier is only active when needed to further amplify the RF signal beyond the average output power. Herein, an activation point of the peak amplifier is dynamically adjusted in accordance with the average output power of the RF signal. As a result, it is possible to eliminate excessive headroom in the APT voltage to thereby improve efficiency of the power amplifier circuit and the wireless transmission circuit as a whole.

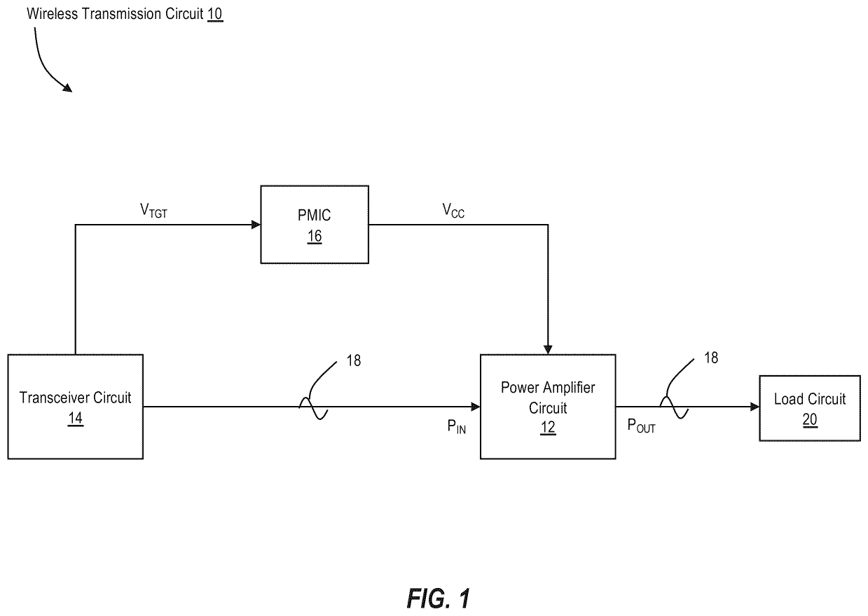

FIG. 1 is a schematic diagram of an exemplary wireless transmission circuit 10 wherein embodiments of the present disclosure can be employed to provide efficiency improvement in a power amplifier circuit 12 and in the wireless transmission circuit 10 as a whole. Herein, the wireless transmission circuit 10 also includes a transceiver circuit 14 and a power management integrated circuit (PMIC) 16. The transceiver circuit 14 is configured to generate an RF signal 18 and provide the RF signal 18 to the power amplifier circuit 12. The power amplifier circuit 12 is configured to amplify the RF signal 18 from an input power P_{IN} to an output power P_{OUT} based on an APT voltage V_{CC} and provide the amplified RF signal 18 to a load circuit 20 (e.g., an RF front-end circuit and/or an antenna circuit) for transmission. The PMIC 16 is configured to generate the APT voltage V_{CC} based on a target voltage V_{TGT}. The target voltage V_{TGT} is generated by the transceiver circuit 14 in accordance with the output power P_{OUT}.

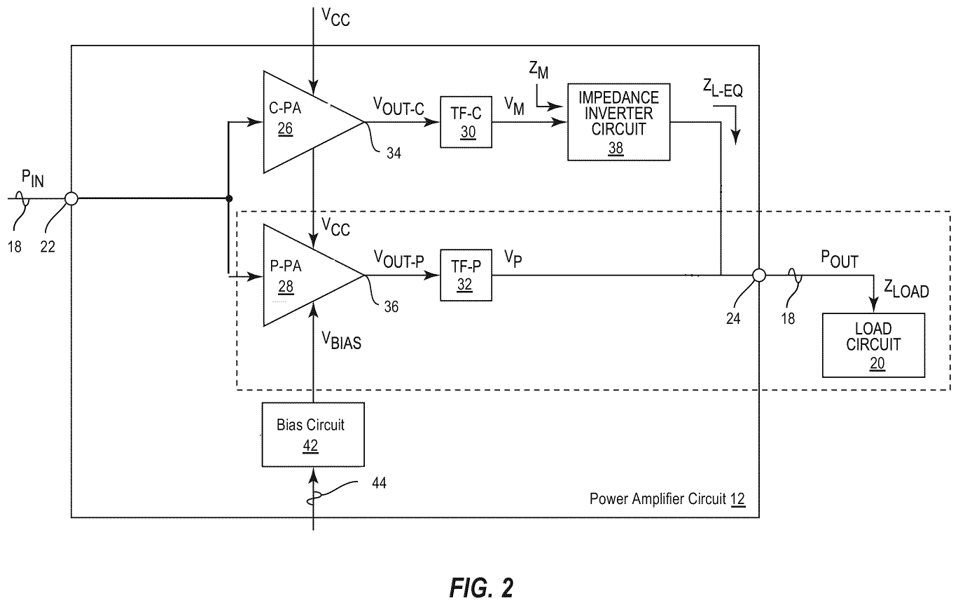

In an embodiment, the power amplifier circuit 12 can be a Doherty power amplifier circuit. In this regard, FIG. 2 is a schematic diagram of the power amplifier circuit 12 in the wireless transmission circuit 10 of FIG. 1. Common elements between FIGS. 1 and 2 are shown therein with common element numbers and will not be re-described herein.

The power amplifier circuit 12 includes a signal input 22 that receives the RF signal 18. The power amplifier circuit 12 also includes a signal output 24 that outputs the amplified RF signal 18 to the load circuit 20, which inherently presents a load impedance Z_{LOAD} to the power amplifier circuit 12.

The power amplifier circuit 12 also includes a carrier amplifier 26 (denoted as “C-PA”) and a peak amplifier 28 (denoted as “P-PA”). The carrier amplifier 26 and the peak amplifier 28, which are coupled in parallel between the signal input 22 and the signal output 24, are configured to collectively amplify the RF signal 18 from the input power P_{IN} to the output power P_{OUT} based on the APT voltage V_{CC}.

The power amplifier circuit 12 includes a carrier load-line transfer function (TF) circuit 30 (denoted as “TF-C”) and a peak load-line TF circuit 32 (denoted as “TF-P”). The carrier load-line TF circuit 30 is coupled to an output 34 of the carrier amplifier 26, and the peak load-line TF circuit 32 is coupled to an output 36 of the peak amplifier 28.

The power amplifier circuit 12 also includes an impedance inverter circuit 38 that is coupled between the carrier load-line TF circuit 30 and the peak load-line TF circuit 32. The impedance inverter circuit 38 is configured to create a modulated load impedance Z_{M} based on an equivalent load impedance Z_{L-EQ}. Herein, the equivalent load impedance Z_{L-EQ} represents a total impedance presented to the impedance inverter circuit 38 by the load circuit 20, the peak load-line TF circuit 32, and the peak amplifier 28.

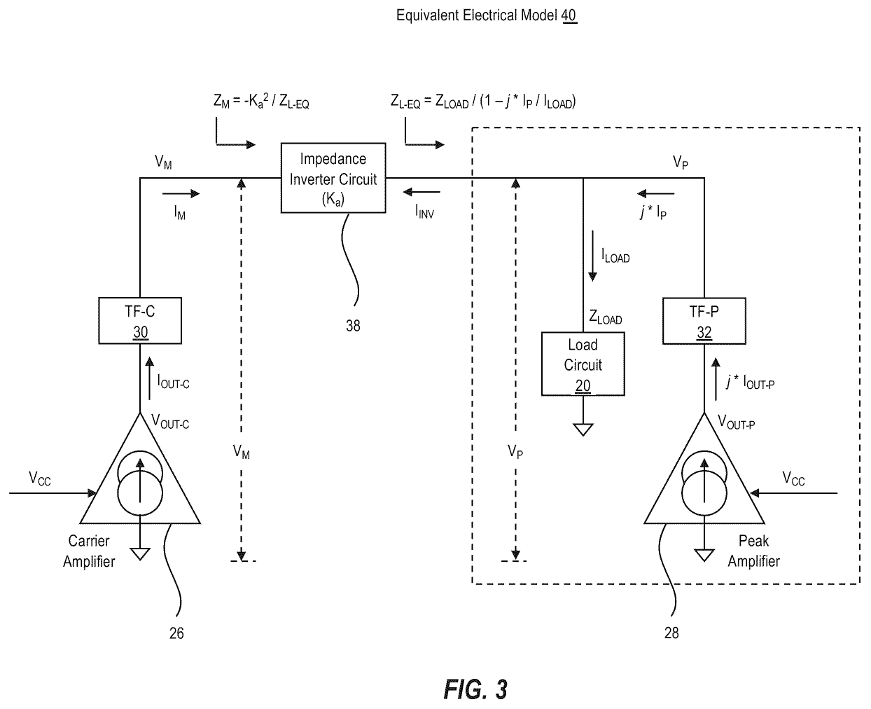

The operational theory and principle behind the power amplifier circuit 12 can be better explained based on an equivalent electrical model. In this regard, FIG. 3 is a schematic diagram illustrating an exemplary equivalent electrical model 40 of the power amplifier circuit 12 in FIG. 2. Common elements between FIGS. 2 and 3 are shown therein with common element numbers and will not be re-described herein.

The carrier amplifier 26 is configured to generate a carrier output voltage V_{OUT-C} and a carrier output current I_{OUT-C}. Likewise, the peak amplifier 28 is configured to generate a peak output voltage V_{OUT-P} and a peak output current j*I_{OUT-P}. The carrier load-line TF circuit 30 transforms the carrier output voltage V_{OUT-C} and the carrier output current I_{OUT-C} into a time-variant carrier voltage envelope V_{M} and a time-variant carrier current I_{M} in accordance with Equations 1 and 2, respectively. The peak load-line TF circuit 32 transforms the peak output voltage V_{OUT-P} and the peak output current j*I_{OUT-P} into a time-variant peak voltage envelope V_{P} and a time-variant peak current j*I_{P} in accordance with Equations 3 and 4, respectively.

$${V}_{M} = {V}_{OUT - C} * TFC \qquad ( Eq . 1 )$$

$${I}_{M} = {I}_{OUT - C} * TFC \qquad ( Eq . 2 )$$

$${V}_{P} = {V}_{OUT - P} * TFP \qquad ( Eq . 3 )$$

$$j * {I}_{P} = j * {I}_{OUT - P} * TFP \qquad ( Eq . 4 )$$

In the equations above, TFC represents a carrier load-line transfer function implemented by the carrier load-line TF circuit 30, and TFP represents a peak load-line transfer function implemented by the peak load-line TF circuit 32. A relationship between the time-variant peak voltage envelope V_{P} and the time-variant carrier current I_{M} can be expressed in Equation 5 below.

$${V}_{P} = {K}_{a} * {I}_{M} \qquad ( Eq . 5 )$$

In the Equation 5, Kₐ represents a coefficient of the impedance inverter circuit 38. The equivalent load impedance Z_{L-EQ}, which represents the total impedance of the load circuit 20, the peak load-line TF circuit 32, and the peak amplifier 28, can be expressed as in Equation 6 below.

$${Z}_{LE - Q} = {Z}_{LOAD} / ( 1 - j * {I}_{P} / {I}_{LOAD} ) \qquad ( Eq . 6 )$$

In the above equation (Eq. 6), Z_{LOAD} represents the inherent load impedance Z_{LOAD} of the load circuit 20, and I_{LOAD} represents a load current in the load circuit 20. From Equation 6, it can be seen that when j*I_{P}=0, which is an indication that the peak amplifier 28 is deactivated, the equivalent load impedance Z_{L-EQ} will only include the inherent load impedance Z_{LOAD}. However, when j*I_{P}=½ Z_{LOAD}, for example, the equivalent load impedance Z_{L-EQ} will change to 2*Z_{LOAD}. In this regard, the equivalent load impedance Z_{L-EQ} will increase when the peak amplifier 28 is activated.

The impedance inverter circuit 38 is configured to convert the equivalent load impedance Z_{L-EQ} into a modulated load impedance Z_{M} in accordance with Equation 7 below.

$${Z}_{M} = - {K}_{a}^{2} / {Z}_{L - EQ} = - {K}_{a}^{2} * ( 1 - j * {I}_{P} / {I}_{LOAD} ) / {Z}_{LOAD} \qquad ( Eq . 7 )$$

From Equation 7, it can be seen that the modulated load impedance Z_{M} will decrease when the equivalent load impedance Z_{L-EQ} increases. In this regard, it is possible to reduce the modulated load impedance Z_{M} by activating the peak amplifier 28. The time-variant carrier voltage envelope V_{M} can be determined based on Equation 8 below.

$${V}_{M} = 4 * {Z}_{LOAD} * ( {I}_{M} - 1 / 2 {I}_{P} ) \qquad ( Eq . 8 )$$

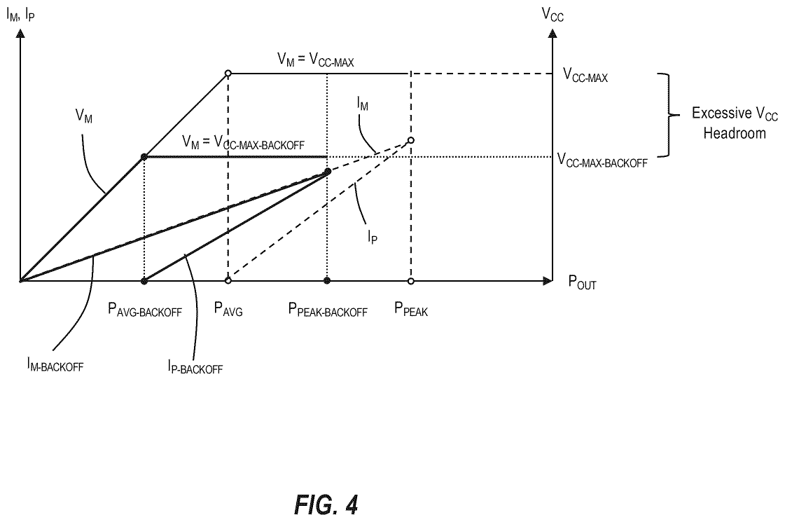

With reference back to FIG. 2, the carrier amplifier 26 is always active to amplify the RF signal 18 regardless of the output power P_{OUT}. In contrast, the peak amplifier 28 is only activated when the output power P_{OUT} is above a certain level. FIG. 4 is a graphic diagram providing an exemplary illustration of a typical operation scheme of the power amplifier circuit 12 and an efficiency improvement scheme that can be implemented in the power amplifier circuit 12 to provide efficiency improvement over the typical operation scheme. Common elements between FIGS. 2, 3, and 4 are shown therein with common element numbers and will not be re-described herein.

In the typical operation scheme, when the output power P_{OUT} is lower than an average output power P_{AVG}, the peak amplifier 28 is deactivated. Accordingly, the time-variant peak current I_{P} will not be present. The carrier amplifier 26, on the other hand, is active to drive the time-variant carrier voltage envelope V_{M} up toward a maximum (denoted as “V_{cc}-MAX”) of the APT voltage V_{CC} and increase the time-variant carrier current I_{M} to drive the output power P_{OUT} toward the average output power P_{AVG}.

When the output power Pₒᵤᵣ becomes higher than or equal to the average output power P_{AVG}, the carrier amplifier 26 maintains the time-variant carrier voltage envelope V_{M} at the maximum of the APT voltage V_{CC} (V_{M}=V_{CC-MAX}) but continues to increase the time-variant carrier current I_{M}. In the meantime, the peak amplifier 28 is activated to provide the time-variant peak current I_{P}. Collectively, the time-variant carrier current I_{M} and the time-variant peak current I_{P} can drive the output power P_{OUT} toward a peak output power P_{PEAK}. Notably at the peak output power P_{PEAK}, the time-variant carrier current I_{M} will be equal to the time-variant peak current I_{P}.

Under certain dynamic scenarios, the average output power P_{AVG} may need to be reduced to a backoff level P_{AVG-BACKOFF} (e.g., P_{AVG-BACKOFF}=P_{AVG}−3 dB or 6 dB). As such, the peak output power P_{PEAK} will also be reduced to a backoff level P_{PEAK-BACKOFF} (e.g., P_{PEAK-BACKOFF}=P_{PEAK}−3 dB or 6 dB). Accordingly, the APT voltage V_{CC} needed for amplifying the RF signal 18 will be reduced to a backoff level V_{CC-BACKOFF} as well. Under such scenarios, if the peak amplifier 28 is still activated at the original average output power P_{AVG}, the carrier amplifier 26 will drive the time-variant carrier voltage envelope V_{M} toward the maximum of the APT voltage V_{CC-MAX} instead of the backoff APT voltage V_{CC-BACKOFF}, thus causing an excessive APT voltage headroom (V_{CC-MAX}−V_{CC-BACKOFF}). In addition, the carrier amplifier 26 and the peak amplifier 28 will produce an excessive amount of the time-variant carrier current I_{M} and the time-variant peak current I_{P} to drive the output power P_{OUT} toward the peak output power P_{PEAK} instead of the backoff peak output power P_{PEAK-BACKOFF}. As a result, the power amplifier circuit 12, and the wireless transmission circuit 10 as a whole, can suffer decreased efficiency and increased power consumption.

In this regard, according to the efficiency improvement scheme described herein, the peak amplifier 28 will be activated at the backoff average output power P_{AVG}-BACKOFF. As illustrated herein, when the output power P_{OUT} is lower than the backoff average output power P_{AVG-BACKOFF}, the peak amplifier 28 is deactivated. The carrier amplifier 26, on the other hand, is active to drive the time-variant carrier voltage envelope V_{M} up toward the backoff APT voltage V_{CC-BACKOFF} and increase a time-variant carrier current I_{M-BACKOFF} to drive the output power P_{OUR} toward the backoff average output power P_{AVG-BACKOFF}.

When the output power P_{OUR} becomes higher than or equal to the backoff average output power P_{AVG-BACKOFF}, the carrier amplifier 26 maintains the time-variant carrier voltage envelope V_{M} at the backoff APT voltage V_{CC-BACKOFF} (V_{M}=V_{CC-BACKOFF}) but continues to increase the time-variant carrier current I_{M-BACKOFF}. In the meantime, the peak amplifier 28 is activated to provide a time-variant peak current I_{P-BACKOFF}. Collectively, the time-variant carrier current I_{M-BACKOFF} and the time-variant peak current I_{P-BACKOFF} can drive the output power P_{OUT} toward the backoff peak output power P_{PEAK-BACKOFF}. Notably at the backoff peak output power P_{PEAK-BACKOFF}, the time-variant carrier current I_{M-BACKOFF} will be equal to the time-variant peak current I_{P-BACKOFF}. Thus, by adjusting the activation point of the peak amplifier 28, it is possible to eliminate the excessive APT voltage headroom to thereby improve efficiency of the power amplifier circuit 12 and the wireless transmission circuit 10 as a whole.

Notably herein, either the average output power P_{AVG} or the backoff average output power P_{AVG-BACKOFF} can be referred to as a “threshold value,” depending on how the wireless transmission circuit 10 is configured to operate. Specifically, when the wireless transmission circuit 10 is configured to operate based on the average output power P_{AVG}, the threshold value refers to the average output power P_{AVG}. In contrast, when the wireless transmission circuit 10 is configured to operate based on the backoff average output power P_{AVG-BACKOFF}, the threshold value refers to backoff average output power P_{AVG-BACKOFF}.

With reference back to FIG. 2, the power amplifier circuit 12 can include a bias circuit 42 that can activate the peak amplifier 28 by providing a bias voltage V_{BIAS} or deactivate the peak amplifier 28 by not providing the bias voltage V_{BIAS}. In an embodiment, the bias circuit 42 may be configured, by default, to activate the peak amplifier 28 at the average output power P_{AVG}. In response to receiving an indication signal 44 (e.g., from the transceiver circuit 14) that indicates the output power P_{OUT} is reduced from the average output power P_{AVG} to the backoff average output power P_{AVG-BACKOFF}, the bias circuit 42 can generate the bias voltage V_{BIAS} to activate the peak amplifier 28 at the backoff average output power P_{AVG-BACKOFF}.

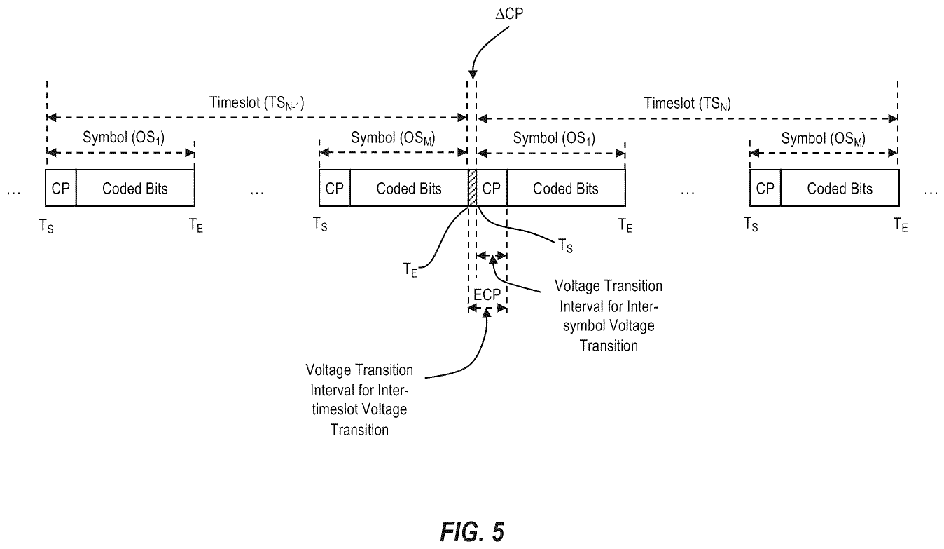

In an embodiment, the bias circuit 42 may be configured to adjust the activation point of the peak amplifier 28 on a per-symbol or a per-timeslot basis. In this regard, FIG. 5 illustrates a pair of consecutive timeslots TS_{N-1}, TS_{N}, each of which includes multiple orthogonal frequency division multiplexing (OFDM) symbols OS₁-OS_{M}. Notably, each of the OFDM symbols OS₁-OS_{M} has a symbol duration that depends on a subcarrier spacing (SCS) as defined in third-generation partnership project (3GPP) standards. Each of the OFDM symbols OS₁-OS_{M} is bound by a respective start time T_{S} and a respective end time T_{E} and includes a cyclic prefix (CP) and multiple coded bits. The CP duration will be set once the SCS is chosen. Likewise, the duration of the timeslots TS_{N-1}, TS_{N} is determined by the duration of the OFDM symbols OS₁-OS_{M}. In this regard, the duration of the timeslots TS_{N-1}, TS_{N} also depends on the SCS.

The timeslots TS_{N-1} and TS_{N} are further separated by an extra CP (ΔCP) located between the end time T_{E} of the last OFDM symbol OS_{M} in the preceding timeslot TS_{N-1} and the start time T_{S} of the first OFDM symbol OS₁ in the succeeding timeslot TS_{N}. The extra CP (ΔCP) and the CP of the first OFDM symbol OS₁ in the succeeding timeslot TS_{N} collectively provide an extended CP (ECP) (ECP=ΔCP+CP) between the preceding timeslot TS_{N-1} and the succeeding timeslot TS_{N}. In context of the present disclosure, the duration of each of the OFDM symbols OS₁-OS_{M} and the duration of each of the timeslots TS_{N-1}, TS_{N} can both be referred to as a voltage modulation interval, depending on whether the APT voltage V_{CC} is modulated on an inter-symbol or an inter-timeslot basis.

Specifically, when the APT voltage V_{CC} is adapted between each of the OFDM symbols OS₁-OS_{M} in each of the timeslots TS_{N-1}, TS_{N}, the voltage modulation interval (also referred to as “inter-symbol voltage modulation interval”) corresponds to the duration of each of the OFDM symbols OS₁-OS_{M}. In this regard, the APT voltage V_{CC} transitions (increases or decreases) between consecutive ones of the OFDM symbols OS₁-OS_{M} and must be completed within the CP in each of the OFDM symbols OS₁-OS_{M}. Accordingly, the CP in each of the OFDM symbols OS₁-OS_{M} defines a voltage transition interval (also referred to as “inter-symbol voltage transition interval”) for completing an inter-symbol voltage transition.

In contrast, when the APT voltage V_{CC} is adapted between each of the timeslots TS_{N-1}, TS_{N}, the voltage modulation interval (also referred to as “inter-timeslot voltage modulation interval”) corresponds to the duration of each of the timeslots TS_{N-1}, TS_{N}. In this regard, the APT voltage V_{CC} transitions (increases or decreases) and must be completed within the extended CP (ECP) between the preceding timeslot TS_{N-1} and the succeeding timeslot TS_{N}. Accordingly, the extended CP (ECP) defines the voltage transition interval (also referred to as “inter-timeslot voltage transition interval”) for inter-timeslot voltage transition.

When the bias circuit 42 is configured to adapt the activation point of the peak amplifier 28 on the per-symbol basis, the bias circuit 42 will receive the indication signal 44 prior to the CP in the succeeding one of each adjacent pair of the OFDM symbols OS₁-OS_{M}. As an example, to adapt the activation point of the peak amplifier 28 during the OFDM symbol OS₂, the bias circuit 42 will receive the indication signal 44 prior to the end time T_{E} of the OFDM symbol OS₁.

When the bias circuit 42 is configured to adapt the activation point of the peak amplifier 28 on the per-timeslot basis, the bias circuit 42 will receive the indication signal 44 prior to a start of the ECP between each adjacent pair of the timeslots TS_{N-1}, TS_{N}. As an example, to adapt the activation point of the peak amplifier 28 during the timeslot TS_{N}, the bias circuit 42 will receive the indication signal 44 prior to the start of the ECP.

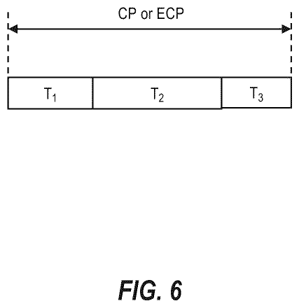

In an embodiment, the voltage transition interval (CP or ECP) can be further divided into multiple sections to serve multiple purposes. FIG. 6 is a schematic diagram illustrating a configuration of the voltage transition interval in FIG. 5.

Herein, a voltage transition interval (CP for inter-symbol transition and ECP for inter-timeslot transition) can be divided into a first subinterval T₁, a second subinterval T₂, and a third subinterval T₃. The first subinterval T1 may be configured for the PMIC to adapt the APT voltage V_{cc} and for the bias circuit 42 to adapt the activation point of the peak amplifier 28. The second subinterval T₂ may be configured for the transceiver circuit 14 to measure a gain change, an amplitude modulation-amplitude modulation (AM-AM), and/or an amplitude modulation-phase modulation (AM-PM) change at the power amplifier circuit 12. The third subinterval T₃ may be configured for the transceiver circuit 14 to apply corrective actions in response to the measured gain change, the measured AM-AM change, and/or the AM-PM change. Such corrective actions may include, for example, digital predistortion (DPD) and adjustment to the input power P_{IN} of the RF signal 18.

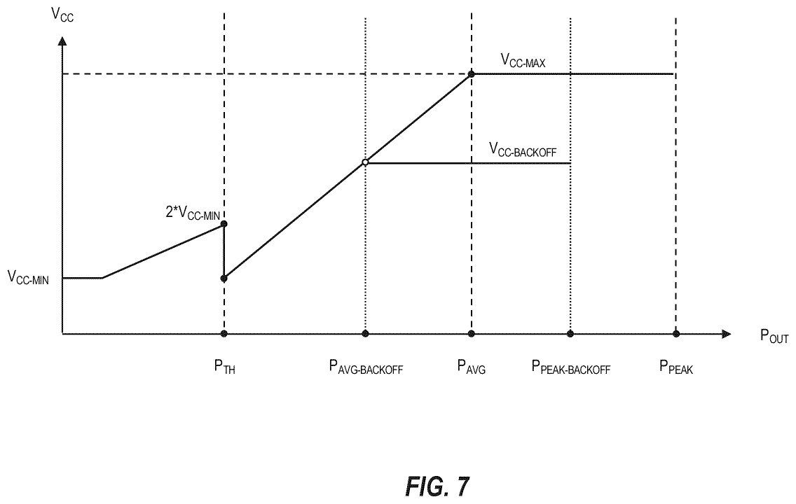

To help reduce in-rush current in the power amplifier circuit 12, the efficiency improvement scheme described above may be further adapted to disable the peak amplifier 28 completely when the average output power P_{AVG} is below a predefined power threshold P_{TH}. FIG. 7 is a graphic diagram providing an exemplary illustration of another efficiency improvement scheme according to another embodiment of the present disclosure.

Herein, the bias circuit 42 is configured not to generate the bias voltage V_{BIAS} when the output power P_{OUT} of the RF signal 18 is lower than the predefined power threshold P_{TH} (P_{OUT}<P_{TH}). Accordingly, the peak amplifier 28 will be completely disabled. In the meantime, the PMIC 16 is configured to generate the APT voltage V_{CC} between a minimum voltage V_{CC-MIN} and approximately twice the minimum voltage V_{CC-MIN} (2*V_{CC-MIN}) (V_{CC-MIN}≤V_{cc}≤2*V_{CC-MIN}).

When the output power P_{OUT} is higher than or equal to the predefined threshold power P_{TH} but lower than the backoff average output power P_{AVG-BACKOFF} (P_{TH}≤P_{OUT}<P_{AVG-BACKOFF}), the PMIC 16 will be configured to generate the APT voltage V_{CC} between the minimum voltage V_{CC-MIN} and the backoff APT voltage V_{CC-BACKOFF} (V_{CC-MIN}≤V_{CC}≤V_{CC-BACKOFF}). When the output power P_{OUT} is higher than or equal to the backoff average output power P_{AVG-BACKOFF} (P_{OUT}≥P_{AVG-BACKOFF}), the PMIC 16 will be configured to generate the APT voltage V_{CC} between the minimum voltage V_{CC-MIN} and the maximum APT voltage V_{CC-MAX} (V_{CC-MIN}≤V_{CC}≤V_{CC-MAX}).

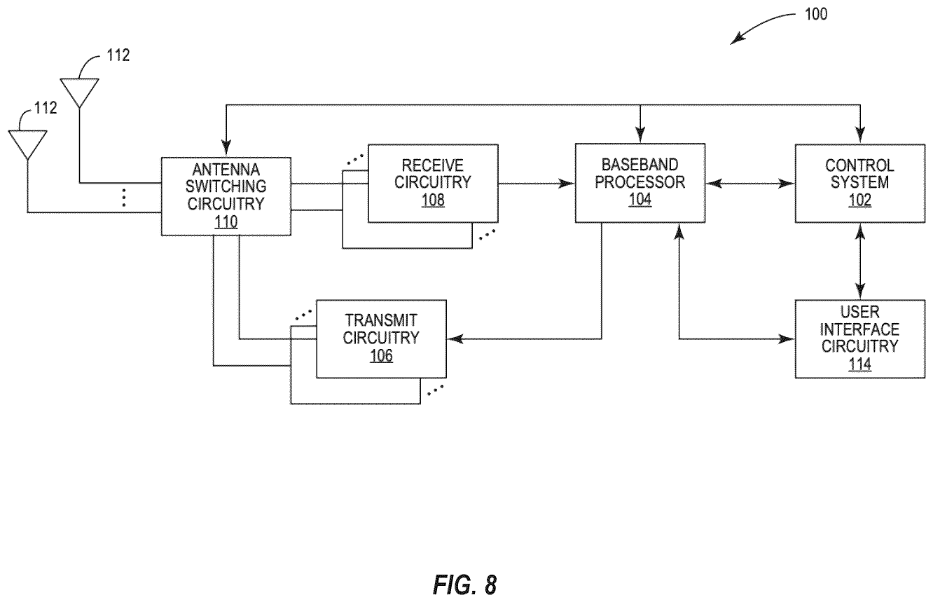

The wireless transmission circuit 10 of FIG. 1 can be provided in a communication device to support the embodiments described above. In this regard, FIG. 8 is a schematic diagram of an exemplary communication device 100 wherein the wireless transmission circuit 10 of FIG. 1 can be provided.

Herein, the communication device 100 can be any type of communication devices, such as mobile terminals, smart watches, tablets, computers, navigation devices, access points, and like wireless communication devices that support wireless communications, such as cellular, wireless local area network (WLAN), Bluetooth, and near-field communications. The communication device 100 will generally include a control system 102, a baseband processor 104, transmit circuitry 106, receive circuitry 108, antenna switching circuitry 110, multiple antennas 112, and user interface circuitry 114. In a non-limiting example, the control system 102 can be a field-programmable gate array (FPGA), as an example. In this regard, the control system 102 can include at least a microprocessor, an embedded memory circuit, and a communication bus interface. The receive circuitry 108 receives radio frequency signals via the antennas 112 and through the antenna switching circuitry 110 from one or more basestations. A low-noise amplifier and a filter cooperate to amplify and remove broadband interference from the received signal for processing. Downconversion and digitization circuitry (not shown) will then downconvert the filtered, received signal to an intermediate or baseband frequency signal, which is then digitized into one or more digital streams using analog-to-digital converters (ADCs).

The baseband processor 104 processes the digitized received signal to extract the information or data bits conveyed in the received signal. This processing typically comprises demodulation, decoding, and error correction operations, as will be discussed in greater detail below. The baseband processor 104 is generally implemented in one or more digital signal processors (DSPs) and application-specific integrated circuits (ASICs).

For transmission, the baseband processor 104 receives digitized data, which may represent voice, data, or control information, from the control system 102, which it encodes for transmission. The encoded data is output to the transmit circuitry 106, where a digital-to-analog converter (DAC) converts the digitally encoded data into an analog signal and a modulator modulates the analog signal onto a carrier signal that is at a desired transmit frequency or frequencies. A power amplifier will amplify the modulated carrier signal to a level appropriate for transmission and deliver the modulated carrier signal to the antennas 112 through the antenna switching circuitry 110. The multiple antennas 112 and the replicated transmit circuitry 106 and receive circuitry 108 may provide spatial diversity. Modulation and processing details will be understood by those skilled in the art.

In an embodiment, the wireless transmission circuit 10 can be provided in the communication device 100 to include the transmit circuitry 106, the receive circuitry 108, and the antenna switching circuitry 110. It should be appreciated that the wireless transmission circuit 10 can also be provided in the communication device 100 according to other suitable configurations.

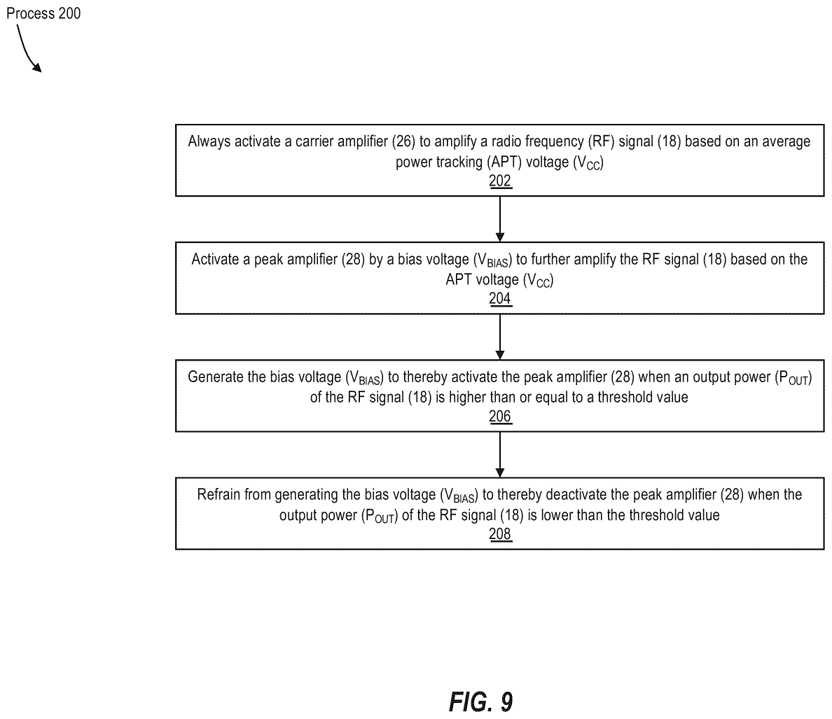

In an embodiment, it is possible to improve efficiency of the wireless transmission circuit 10 of FIG. 1 in accordance with a process. In this regard, FIG. 9 is a flowchart of an exemplary process 200 for improving efficiency of the wireless transmission circuit 10 of FIG. 1.

Herein, the process 200 includes always activating the carrier amplifier 26 to amplify the RF signal 18 based on the APT voltage V_{CC} (step 202). The process 200 also includes activating peak amplifier 28 by the bias voltage V_{BIAS} to further amplify the RF signal 18 based on the APT voltage V_{CC} (step 204). The process 200 also includes generating the bias voltage V_{BIAS} to thereby activate the peak amplifier 28 when the output power P_{OUT} of the RF signal 18 is higher than or equal to a threshold value (step 206). The process 200 also includes refraining from generating the bias voltage V_{BIAS} to thereby deactivate the peak amplifier 28 when the output power P_{OUT} of the RF signal 18 is lower than the threshold value (step 208).

Those skilled in the art will recognize improvements and modifications to the preferred embodiments of the present disclosure. All such improvements and modifications are considered within the scope of the concepts disclosed herein and the claims that follow.

What is claimed is:

1. A wireless transmission circuit comprising:
a power amplifier circuit comprising:
a carrier amplifier always activated to amplify a radio frequency (RF) signal based on an average power tracking (APT) voltage;
a peak amplifier activated by a bias voltage to further amplify the RF signal based on the APT voltage; and
a bias circuit configured to:
generate the bias voltage to thereby activate the peak amplifier when an output power of the RF signal is higher than or equal to a threshold value; and
refrain from generating the bias voltage to thereby deactivate the peak amplifier when the output power of the RF signal is lower than the threshold value;
a power management integrated circuit (PMIC) configured to generate the APT voltage based on a target voltage; and
a transceiver circuit configured to:
generate and provide the RF signal to the power amplifier circuit;
indicate the output power of the RF signal to the bias circuit; and
generate the target voltage based on the output power of the RF signal.

2. The wireless transmission circuit of claim 1, wherein the threshold value is equal to an average output power of the RF signal.

3. The wireless transmission circuit of claim 1, wherein the threshold value is equal to a backoff average output power of the RF signal that is lower than an average output power of the RF signal.

4. The wireless transmission circuit of claim 1, wherein:
the PMIC is further configured to adapt the APT voltage within a voltage transition interval in between each adjacent pair of a plurality of voltage modulation intervals;
the power amplifier circuit is further configured to amplify the RF signal in each of the plurality of voltage modulation intervals; and
the transceiver circuit is further configured to indicate the output power of the RF signal to the bias circuit prior to a start of each of the plurality of voltage modulation intervals.

5. The wireless transmission circuit of claim 4, wherein the voltage transition interval between each adjacent pair of the plurality of voltage modulation intervals comprises:
a first subinterval wherein the PMIC is further configured to adapt the APT voltage;
a second subinterval wherein the transceiver circuit is further configured to measure one or more of a gain change, an amplitude modulation-amplitude modulation (AM-AM) change, and an amplitude modulation-phase modulation (AM-PM) change at the power amplifier circuit; and
a third subinterval wherein the transceiver circuit is further configured to apply one or more corrective actions in response to one or more of the measured gain change, the measured AM-AM change, and the measured AM-PM change.

6. The wireless transmission circuit of claim 4, wherein:
each of the plurality of voltage modulation intervals corresponds to a respective one of a plurality of orthogonal frequency division multiplex (OFDM) symbols each starting with a respective cyclic prefix (CP); and
the voltage transition interval corresponds to the respective CP in a succeeding OFDM symbol of each adjacent pair of the plurality of OFDM symbols.

7. The wireless transmission circuit of claim 4, wherein:
each of the plurality of voltage modulation intervals corresponds to a respective one of a plurality of timeslots each comprising a plurality of orthogonal frequency division multiplex (OFDM) symbols;
each adjacent pair of the plurality of timeslots is separated by a respective extended cyclic prefix (ECP); and
the voltage transition interval corresponds to a respective ECP between each adjacent pair of the plurality of timeslots.

8. The wireless transmission circuit of claim 1, wherein the PMIC is further configured to generate the APT voltage between a minimum APT voltage and approximately twice the minimum APT voltage when the output power of the RF signal is lower than a predefined power threshold.

9. The wireless transmission circuit of claim 8, wherein the bias circuit is further configured not to generate the bias voltage to thereby deactivate the peak amplifier when the output power of the RF signal is lower than the predefined power threshold.

10. The wireless transmission circuit of claim 8, wherein the PMIC is further configured to:
generate the APT voltage between the minimum APT voltage and a backoff APT voltage when the output power of the RF signal is between the predefined power threshold and a backoff average output power; and
generate the APT voltage between the minimum APT voltage and a maximum APT voltage when the output power of the RF signal is higher than the predefined power threshold.

11. A wireless device comprising a wireless transmission circuit, the wireless transmission circuit comprising:
a power amplifier circuit comprising:
a carrier amplifier always activated to amplify a radio frequency (RF) signal based on an average power tracking (APT) voltage;
a peak amplifier activated by a bias voltage to further amplify the RF signal based on the APT voltage; and
a bias circuit configured to:
generate the bias voltage to thereby activate the peak amplifier when an output power of the RF signal is higher than or equal to a threshold value; and
refrain from generating the bias voltage to thereby deactivate the peak amplifier when the output power of the RF signal is lower than the threshold value;
a power management integrated circuit (PMIC) configured to generate the APT voltage based on a target voltage; and
a transceiver circuit configured to:
generate and provide the RF signal to the power amplifier circuit;
indicate the output power of the RF signal to the bias circuit; and
generate the target voltage based on the output power of the RF signal.

12. The wireless device of claim 11, wherein the threshold value is equal to one of:
an average output power of the RF signal; and
a backoff average output power of the RF signal that is lower than the average output power of the RF signal.

13. The wireless device of claim 11, wherein:
the PMIC is further configured to adapt the APT voltage within a voltage transition interval in between each adjacent pair of a plurality of voltage modulation intervals;
the power amplifier circuit is further configured to amplify the RF signal in each of the plurality of voltage modulation intervals; and
the transceiver circuit is further configured to indicate the output power of the RF signal to the bias circuit prior to a start of each of the plurality of voltage modulation intervals.

14. The wireless device of claim 13, wherein the voltage transition interval between each adjacent pair of the plurality of voltage modulation intervals comprises:
a first subinterval wherein the PMIC is further configured to adapt the APT voltage;
a second subinterval wherein the transceiver circuit is further configured to measure one or more of a gain change, an amplitude modulation-amplitude modulation (AM-AM) change, and an amplitude modulation-phase modulation (AM-PM) change at the power amplifier circuit; and
a third subinterval wherein the transceiver circuit is further configured to apply one or more corrective actions in response to one or more of the measured gain change, the measured AM-AM change, and the AM-PM change.

15. The wireless device of claim 13, wherein:
each of the plurality of voltage modulation intervals corresponds to a respective one of a plurality of orthogonal frequency division multiplex (OFDM) symbols each starting with a respective cyclic prefix (CP); and
the voltage transition interval corresponds to the respective CP in a succeeding OFDM symbol of each adjacent pair of the plurality of OFDM symbols.

16. The wireless device of claim 13, wherein:
each of the plurality of voltage modulation intervals corresponds to a respective one of a plurality of timeslots each comprising a plurality of orthogonal frequency division multiplex (OFDM) symbols;
each adjacent pair of the plurality of timeslots is separated by a respective extended cyclic prefix (ECP); and
the voltage transition interval corresponds to a respective ECP between each adjacent pair of the plurality of timeslots.

17. The wireless device of claim 11, wherein the PMIC is further configured to generate the APT voltage between a minimum APT voltage and approximately twice the minimum APT voltage when the output power of the RF signal is lower than a predefined power threshold.

18. The wireless device of claim 17, wherein the bias circuit is further configured not to generate the bias voltage to thereby deactivate the peak amplifier when the output power of the RF signal is lower than the predefined power threshold.

19. The wireless device of claim 17, wherein the PMIC is further configured to:
generate the APT voltage between the minimum APT voltage and a backoff APT voltage when the output power of the RF signal is between the predefined power threshold and a backoff average output power; and
generate the APT voltage between the minimum APT voltage and a maximum APT voltage when the output power of the RF signal is higher than the predefined power threshold.

20. A method for improving wireless transmission efficiency comprising:
always activating a carrier amplifier to amplify a radio frequency (RF) signal based on an average power tracking (APT) voltage;
activating a peak amplifier by a bias voltage to further amplify the RF signal based on the APT voltage;
generating the bias voltage to thereby activate the peak amplifier when an output power of the RF signal is higher than or equal to a threshold value; and
refraining from generating the bias voltage to thereby deactivate the peak amplifier when the output power of the RF signal is lower than the threshold value.
